(19) United States
(12) Patent Application Publication
(10) Pub. No.: US 2013/0292833 A1
(43) Pub. Date: Nov. 7, 2013

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Jae In WON, Seoul (KR); KYHYUN JUNG, Cheonan-si (KR); JaeYong PARK, Cheonan-si (KR)

(73) Assignee: SAMSUNG ELECTRONICS CO., LTD., Suwon-si (KR)

(21) Appl. No.: 13/837,279

(22) Filed: Mar. 15, 2013

(30) Foreign Application Priority Data
May 4, 2012 (KR) 10-2012-0047506

(51) Int. Cl. H01L 23/498

(52) U.S. Cl. CPC H01L 23/49816
USPC 257/738

(57) ABSTRACT

A semiconductor device may include a lower semiconductor package including at least one lower semiconductor chip, at least one upper semiconductor package mounted on the lower semiconductor package to include at least one upper semiconductor chip, a molding layer provided between the lower and upper semiconductor packages, and connection solder balls provided in the molding layer to electrically connect the lower and upper semiconductor packages to each other. Each of the connection solder balls may include a portion protruding upward from the molding layer, and there may be no gap between the connection solder balls and the molding layer.

### CROSS-REFERENCE TO RELATED APPLICATIONS

This U.S. non-provisional patent application claims priority under 35 U.S.C. §119 to Korean Patent Application No. 10-2012-0047506, filed on May 4, 2012, in the Korean Intellectual Property Office, the entire contents of which are hereby incorporated by reference.

### BACKGROUND OF THE INVENTION

1. Field of the Invention

Example embodiments of the inventive concept provide a semiconductor device and a method of fabricating the same.

2. Description of the Related Art

Semiconductor devices are widely used in high performance electronic systems, and the capacity and/or speed of such semiconductor devices is increasing at a rapid pace. Thus, research is carried out in order to integrate multifunctional circuits into ever smaller semiconductor devices and to improve the performance of such semiconductor devices.

In response to such a trend, various semiconductor package techniques have been proposed. For example, methods of stacking a plurality of semiconductor chips on a semiconductor substrate to mount them in a single package or methods of stacking a plurality of packages have been continuously developed. For the package-on-package type devices including a plurality of packages stacked one over the other, since each of the packages may include a semiconductor chip and a package substrate, it is necessary to improve contact reliability at a connection region between packages.

### SUMMARY OF THE INVENTION

Example embodiments of the inventive concept provide a semiconductor device with high reliability.

Additional features and utilities of the present general inventive concept will be set forth in part in the description which follows and, in part, will be obvious from the description, or may be learned by practice of the general inventive concept.

According to example embodiments of the present inventive concept, a semiconductor device may include a lower semiconductor package including at least one lower semiconductor chip, at least one upper semiconductor package mounted on the lower semiconductor package to include at least one upper semiconductor chip, a molding layer provided between the lower and upper semiconductor packages, and connection solder balls provided in the molding layer to electrically connect the lower and upper semiconductor packages to each other. Each of the connection solder balls may include a portion protruding upward from the molding layer, and there may be no gap between the connection solder balls and the molding layer.

In example embodiments, each of the connection solder balls may have a side surface that may be positioned between top and bottom surfaces of the lower molding layer and may be directly covered with the lower molding layer. Each of the connection solder balls may include an upper region and a lower region, and the maximum width of the lower region may be greater than that of the upper region. Further, the upper regions of the connection solder balls may have substantially the same width.

In example embodiments, the lower semiconductor package may include a lower package substrate and the at least one lower semiconductor chip provided on the lower package substrate, and the connection solder balls may be provided on the lower package substrate and around the at least one lower semiconductor chip. The upper semiconductor package may include an upper package substrate, the at least one upper semiconductor chip provided on the upper package substrate, and an upper molding layer covering the upper package substrate and the at least one upper semiconductor chip.

According to example embodiments of the inventive concept, a method of fabricating a semiconductor device may include forming a lower semiconductor package to include a lower semiconductor chip mounted on a lower package substrate, inner solder balls formed on the lower package substrate and around the lower semiconductor chip, and a lower molding layer formed to cover the lower semiconductor chip and the lower package substrate, and mounting an upper semiconductor package on the lower semiconductor package. Top surfaces of the inner solder balls may be formed at a level higher than a top surface of the lower molding layer.

In example embodiments, the mounting of the upper semiconductor package may include forming preliminary solder balls on the upper semiconductor package to be located at positions facing the inner solder balls, and soldering the inner solder balls to the preliminary solder balls to form connection solder balls, and the connection solder balls and the lower molding layer may be formed not to have a gap therebetween. The inner solder balls and the preliminary solder balls may be in contact with each other at a level higher than the top surface of the lower molding layer.

In example embodiments, the forming of the lower semiconductor package may further include partially removing the lower molding layer to form grooves at peripheral regions of the inner solder balls. Each of the grooves may be formed along an exposed periphery of the corresponding one of the inner solder balls with a predetermined width. The mounting of the upper semiconductor package may include forming preliminary solder balls on the upper semiconductor package to be located at positions facing the inner solder balls and the grooves provided therearound, and soldering the inner solder balls to the preliminary solder balls to form connection solder balls. Here, the inner solder balls and the preliminary solder balls may be in contact with each other at a level higher than the top surface of the lower molding layer, and the connection solder balls and the lower molding layer may be formed not to have a gap therebetween.

In example embodiments, the mounting of the upper semiconductor package may include soldering preliminary solder balls on the inner solder balls to form connection solder balls, and mounting the upper semiconductor package on the connection solder balls. The method may further include partially etching the lower molding layer to form grooves at peripheral regions of the connection solder balls, after the forming of the connection solder balls. Each of the inner solder balls may be formed to have a height of 250 μm or more.

According to example embodiments of the inventive concept, a semiconductor device may include: a lower semiconductor package including at least one semiconductor chip on a lower substrate, inner solder balls surrounding the at least one semiconductor chip, and a molding layer fully covering the at least one semiconductor chip and mostly covering the inner solder balls, and an upper semiconductor package including at least one semiconductor chip on a first surface and preliminary solder balls on a second surface, each of the preliminary solder balls being soldered to a corresponding one of the inner solder balls to form a connection so that no interface exists therebeteween.

In an exemplary embodiment, the inner solder balls have a larger diameter and surface area than the preliminary solder balls such that the connection of each of the inner solder balls and the corresponding preliminary solder balls is disposed above the molding layer and there is no gap between the inner solder balls and the molding layer.

According to example embodiments of the inventive concept, another method of fabricating a semiconductor device may include forming a lower semiconductor package including at least one lower semiconductor chip mounted on a lower package substrate, inner solder balls formed on the lower package substrate and around the at least one lower semiconductor chip, and a molding layer formed to cover the at least one semiconductor chip and a portion of the inner solder balls; and soldering preliminary solder balls to exposed portions of corresponding ones of the inner solder balls to form connection solder balls, the preliminary solder balls being disposed on a first surface of an upper semiconductor package, including at least one upper semiconductor chip on a second surface opposite the first surface.

In an exemplary embodiment, the molding layer is formed in butting contact with the inner solder balls such that there is not gap therebetween.

In an exemplary embodiment, the inner solder balls and the preliminary solder balls are in contact with each other at a level higher than the top surface of the lower molding layer.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a sectional view illustrating a semiconductor device according to example embodiments of the inventive concept.

FIGS. 2 through 8 are sectional views illustrating a method of fabricating a semiconductor device according to example embodiments of the inventive concept.

FIG. 9 is an enlarged sectional view of a portion X of FIG. 7.

FIGS. 10 through 13 are sectional views illustrating a semiconductor device and a method of fabricating the same, according to comparative embodiments.

FIG. 14 is an enlarged sectional view of a portion Y of FIG. 13.

FIGS. 15 through 17 are sectional views illustrating a semiconductor device and a method of fabricating the same according to other example embodiments of the inventive concept.

FIG. 18 is an enlarged sectional view of a portion Z of FIG. 16.

FIG. 19 is a sectional view illustrating a semiconductor device according to still other example embodiments of the inventive concept.

FIG. 20 is a perspective view of an electronic apparatus including a semiconductor package according to example embodiments of the inventive concept.

FIG. 21 is a system block diagram of an electronic apparatus including a semiconductor package according to example embodiments of the inventive concept.

FIG. 22 is a block diagram exemplarily illustrating an electronic apparatus including a semiconductor package according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF THE PREFERRED EMBODIMENTS

Example embodiments of the present inventive concept will now be described more fully with reference to the accompanying drawings, in which example embodiments are shown. Example embodiments of the inventive concept may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concept are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concept belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

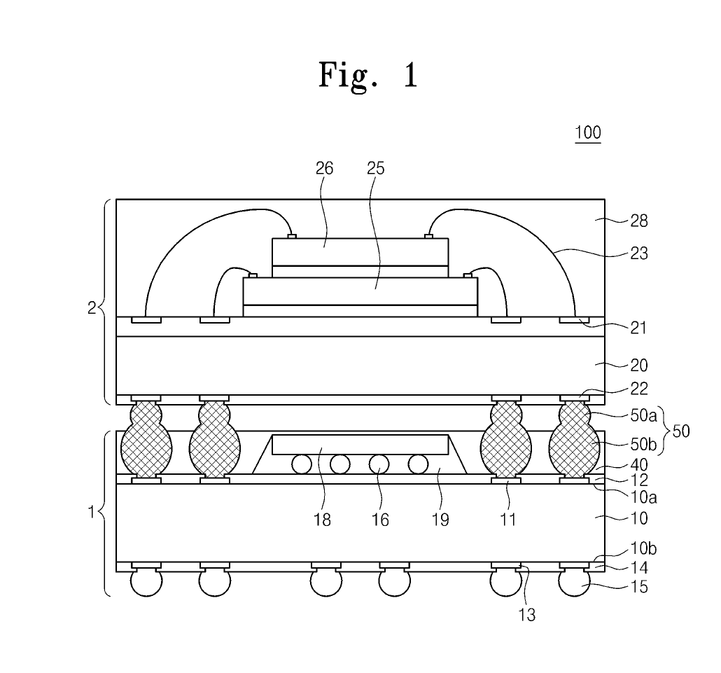

FIG. 1 is a sectional view illustrating a semiconductor device according to example embodiments of the inventive concept.

Referring to FIG. 1, a semiconductor device 100 according to the present embodiment may include a lower semiconductor package 1 and an upper semiconductor package 2 provided on the lower semiconductor package 1. The lower and upper semiconductor packages 1 and 2 may be electrically connected to each other by connection solder balls 50 interposed therebetween.

The lower semiconductor package 1 may include a lower package substrate 10, at least one lower semiconductor chip 18 mounted on the lower package substrate 10, and a lower molding layer 40 covering the lower package substrate 10 and the lower semiconductor chip 18.

The lower package substrate 10 may be a printed circuit board having a single-layered or multi-layered structure. The lower package substrate 10 may include a first surface 10a and a second surface 10b opposing each other. A plurality of first ball lands 11 and a first insulating layer 12 partially covering the same may be provided on the first surface 10a. A plurality of second ball lands 13 and a second insulating layer 14 partially covering the same may be provided on the second surface 10b. External terminals 15 may be provided on the second ball lands 13, thereby serving as an electrical path to exchange electric signals (e.g., voltage) from or to an external device. For example, the external terminals 15 may be solder balls. Although not shown, via patterns and/or circuit patterns may be formed in the lower package substrate 10 to connect the first and second ball lands 11 and 13 with each other.

In example embodiments, the lower semiconductor chip 18 may be mounted on the lower package substrate 10 using internal terminals 16. The internal terminals 16 may be solder balls. Although not shown, the internal terminals 16 may be connected to connection pads (not shown) disposed on the lower package substrate 10. The lower semiconductor chip 18 may be mounted on the lower package substrate 10 in a flip-chip bonding manner or a wire bonding manner. In example embodiments, the number of semiconductor chip 18 mounted on the lower package substrate 10 may be one, as shown in FIG. 1, but example embodiments of the inventive concept may not be limited thereto. For example, a plurality of semiconductor chips may be stacked and mounted on the lower package substrate 10. The semiconductor chip 18 may be a logic chip or a memory chip.

The lower molding layer 40 may be provided to cover the lower package substrate 10 and the lower semiconductor chip 18 of the lower semiconductor package 1. For example, the lower molding layer 40 may be formed to cover at least a side surface of the lower semiconductor chip 18. In example embodiments, the lower molding layer 40 may be formed to cover top and side surfaces of the lower semiconductor chip 18. In other example embodiments, the lower molding layer 40 may be formed to cover the side surface of the lower semiconductor chip 18 and expose the top surface of the lower semiconductor chip 18. The lower molding layer 40 may fasten the lower semiconductor chip 18 to the lower package substrate 10 and/or protect the lower semiconductor chip 18. The lower molding layer 40 may include an epoxy molding compound (EMC). An under-fill resin layer 19 may be further provided between the lower package substrate 10 and the lower semiconductor chip 18.

The upper semiconductor package 2 may include an upper package substrate 20, upper semiconductor chips 25 and 26 mounted on the upper package substrate 20, and an upper molding layer 28 covering the upper semiconductor chips 25 and 26 and the upper package substrate 20. In example embodiments, the upper package substrate 20 may include a multi-layered structure of insulating layers. First connection pads 21 may be provided on a top surface of the upper package substrate 20, and second connection pads 22 may be provided on a bottom surface of the upper package substrate 20. The upper semiconductor chips 25 and 26 may be electrically connected to the first connection pads 21 via wires 23. The second connection pads 22 may be provided at positions corresponding to the first ball lands 11 of the lower semiconductor package 1. Although not shown, via patterns and/or circuit patterns may be formed in the upper package substrate 20.

The connection solder balls 50 may be disposed in the lower molding layer 40. The connection solder balls 50 may be disposed on the lower package substrate 10 and around the lower semiconductor chip 18. The connection solder balls 50 may be disposed on the first ball land 11 of the lower package substrate 10. The connection solder balls 50 may be disposed in the lower molding layer 40, but a portion of a top surface thereof may be exposed outward from the lower molding layer 40. For example, the connection solder balls 50 may be provided in such a way that a bottom surface thereof may be electrically connected to the first ball land 11 and the top surface thereof may be electrically connected to the second connection pads 22 of the upper semiconductor package 2 beyond the lower molding layer 40. Accordingly, the lower semiconductor package 1 and the upper semiconductor package 2 may be electrically connected to each other, thereby forming a package-on-package type semiconductor device.

Each of the connection solder balls 50 may include an upper region 50a and a lower region 50b. The lower region 50b may be provided to have a size or volume greater than the upper region 50a. In other words, the maximum width of the lower region 50b may be greater than that of the upper region 50a. A top surface of the lower region 50b may be located at a level higher than that of the lower molding layer 40.

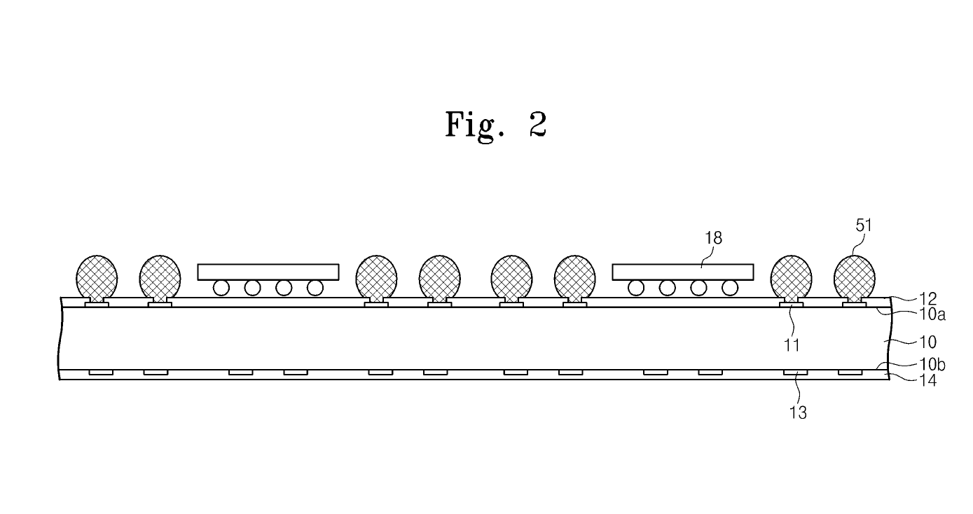

In the present embodiment, the semiconductor device 100 may be provided to have no gap between the connection solder balls 50 and the lower molding layer 40. In other words, the lower region 50b of the connection solder balls 50 may protrude upward from the top surface of the lower molding layer 40, and the top surface of the lower region 50b may be located at the level higher than that of the lower molding layer 40. Accordingly, the connection solder balls 50 may have side surfaces that are in direct contact with the lower molding layer 40 without a gap therebetween, and this enables to improve contact reliability between the lower molding layer 40 and the connection solder balls 50. This will be described in more detail with reference to FIGS. 2 through 8.

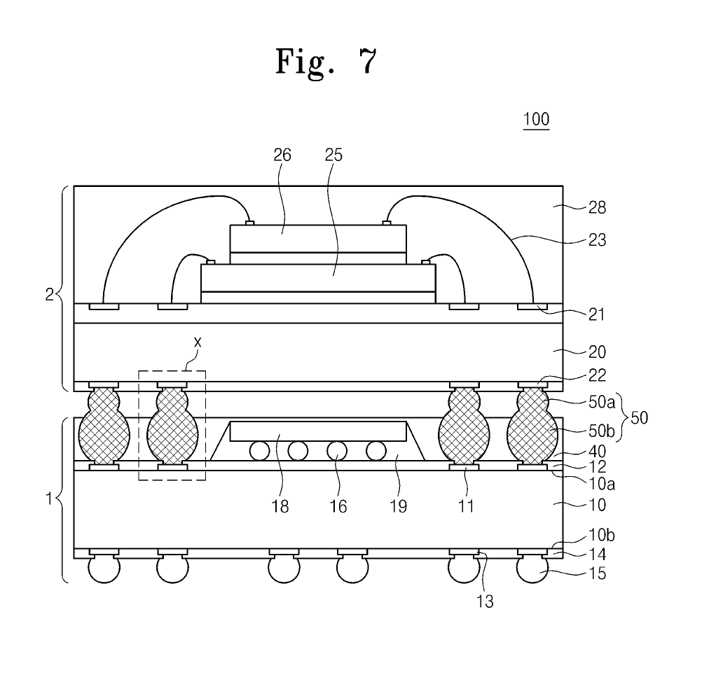

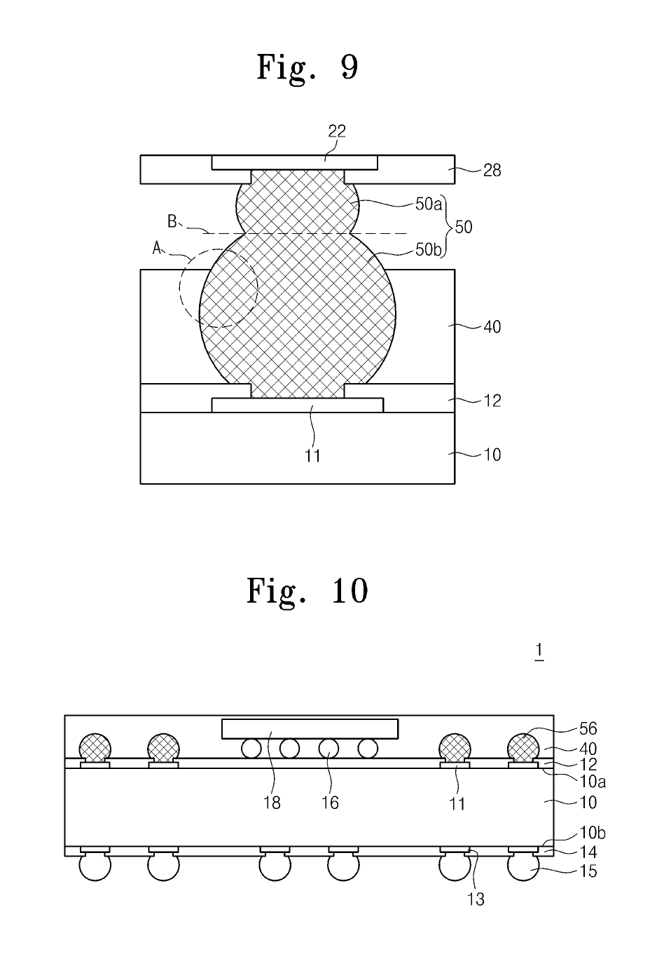

FIGS. 2 through 8 are sectional views illustrating a method of fabricating a semiconductor device according to example embodiments of the inventive concept, and FIG. 9 is an enlarged sectional view of a portion X of FIG. 7.

Referring to FIG. 2, the lower package substrate 10 may be prepared to fabricate the lower semiconductor package 1. The lower package substrate 10 may be for example a single- or multi-layered printed circuit board having a panel/strip size. The lower package substrate 10 may include the first surface 10a and the second surface 10b opposing each other. A plurality of the first ball lands 11 and the first insulating layer 12 partially covering the same may be formed on the first surface 10a. The plurality of second ball lands 13 and the second insulating layer 14 partially covering the same may be formed on the second surface 10b. Although not shown, the via patterns and/or the circuit patterns may be formed in the lower package substrate 10 to electrically connect the first and second lower ball lands 11 and 13 with each other. The lower semiconductor chip 18 may be mounted on the lower package substrate 10 using the internal terminals 16 (see FIG. 1). The internal terminals 16 may be solder balls.

In example embodiments, the lower semiconductor chip 18 may be mounted on the lower package substrate 10 in a flip chip bonding manner. This enables to decrease a length of an electrical path between the lower package substrate 10 and the lower semiconductor chip 18, and thus, it is possible to improve a signal transferring speed therebetween. In other embodiments, the lower semiconductor chip 18 may be mounted on the lower package substrate 10 in a wire bonding manner, but example embodiments of the inventive concept may not be limited thereto.

A plurality of the lower semiconductor chips 18 may be mounted on the lower package substrate 10 having the single panel/strip size. For example, each of the lower semiconductor chips 18 may be mounted on the corresponding one of unit package regions of the single panel/strip sized lower package substrate 10. In other embodiments, a plurality of the lower semiconductor chips 18 may be stacked on the corresponding one of the unit package regions of the lower package substrate 10.

Inner solder balls 51 may be formed on the first ball lands 11, respectively. The inner solder balls 51 may be formed on the lower package substrate 10 and around the lower semiconductor chip 18. The inner solder balls 51 may be configured to electrically connect the lower semiconductor package 1 with the upper semiconductor package to be provided in a subsequent process. In example embodiments, the inner solder balls 51 may be formed to have a diameter or a size greater than those of the internal terminals 16. For example, each of the inner solder balls 51 may be formed to have a top surface higher than that of the lower semiconductor chip 18. In example embodiments, each of the inner solder balls 51 may have a height of 250 μm or more.

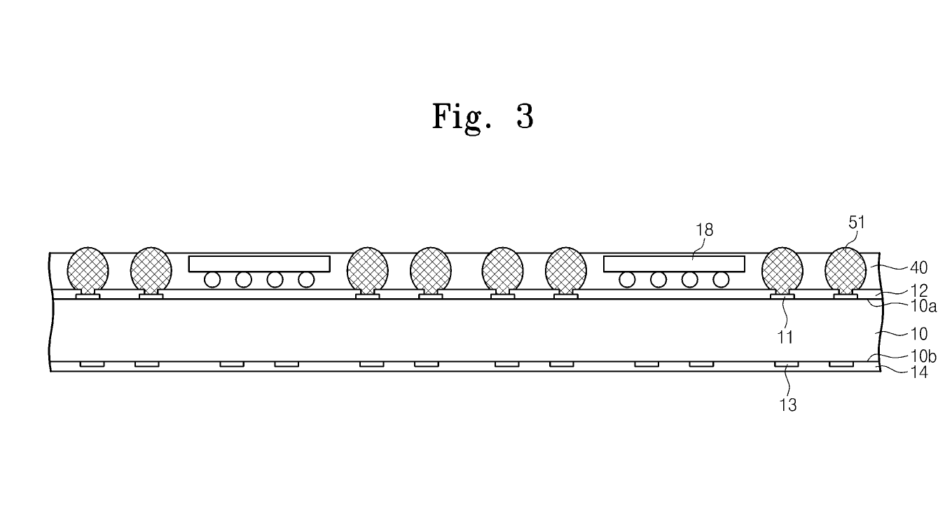

Referring to FIG. 3, the lower molding layer 40 may be formed to cover the lower package substrate 10 and the lower semiconductor chip 18. The lower molding layer 40 may be formed to cover at least a side surface of the lower semiconductor chip 18. For example, the lower molding layer 40 may be formed to cover the top surface of the lower semiconductor chip 18, as shown in FIG. 3, or to cover the side surface of the lower semiconductor chip 18 while exposing the top surface of the lower semiconductor chip 18. The lower molding layer 40 may fasten the lower semiconductor chip 18 and the inner solder balls 51 to the lower package substrate 10 and/or protect the lower semiconductor chip 18 and the inner solder balls 51.

The lower molding layer 40 may be formed to partially expose the inner solder balls 51. In other words, the lower molding layer 40 may be formed to have a top surface lower than those of the second inner solder balls 51, and thus, upper portions of the inner solder balls 51 may not be covered with the lower molding layer 40. The under-fill resin layer 19 (see FIG. 1) may be further provided between the lower package substrate 10 and the lower semiconductor chip 18.

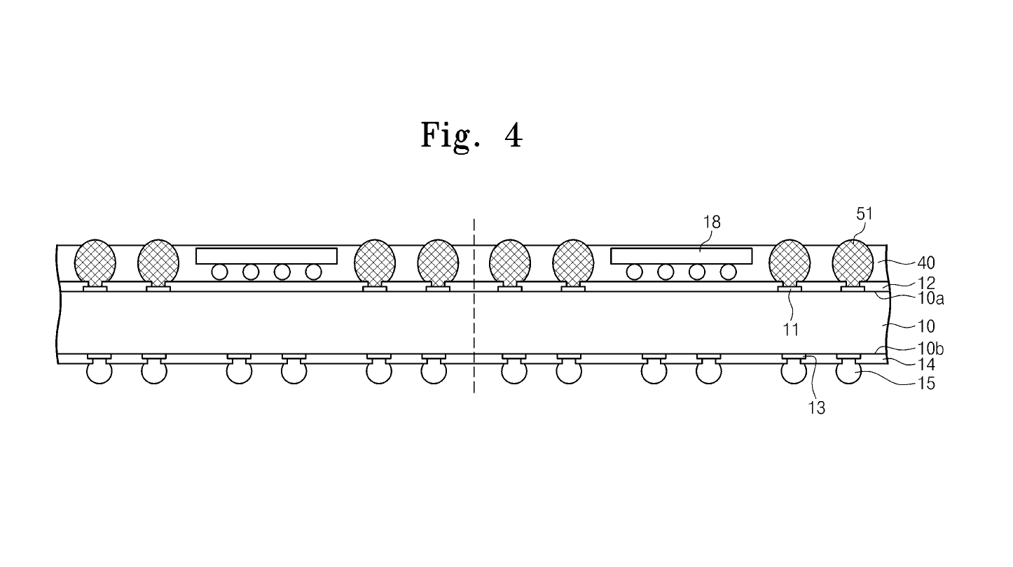

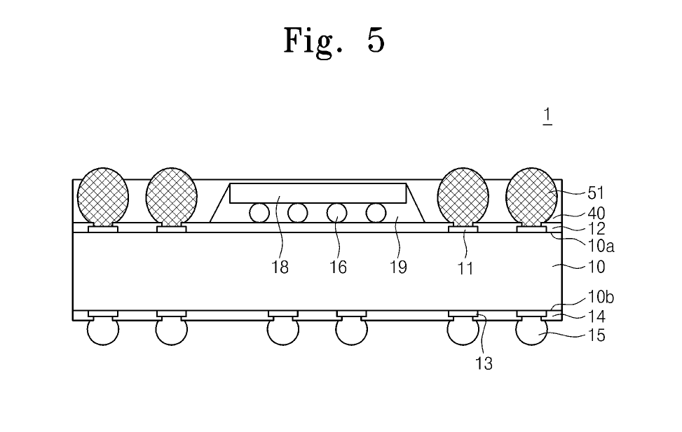

Referring to FIGS. 4 and 5, the external terminals 15 may be formed on the second ball lands 13, respectively. The external terminals 15 may serve as electrical paths for exchanging electronic signals (e.g., voltage) between the lower semiconductor package 1 and an external device. For example, the external terminals 15 may be solder balls.

Thereafter, a singulation process may be performed to separate the unit package regions of the lower package substrate 10 from each other. As the result of the singulation process, the lower semiconductor package 1 may be prepared to have a structure shown in FIG. 5.

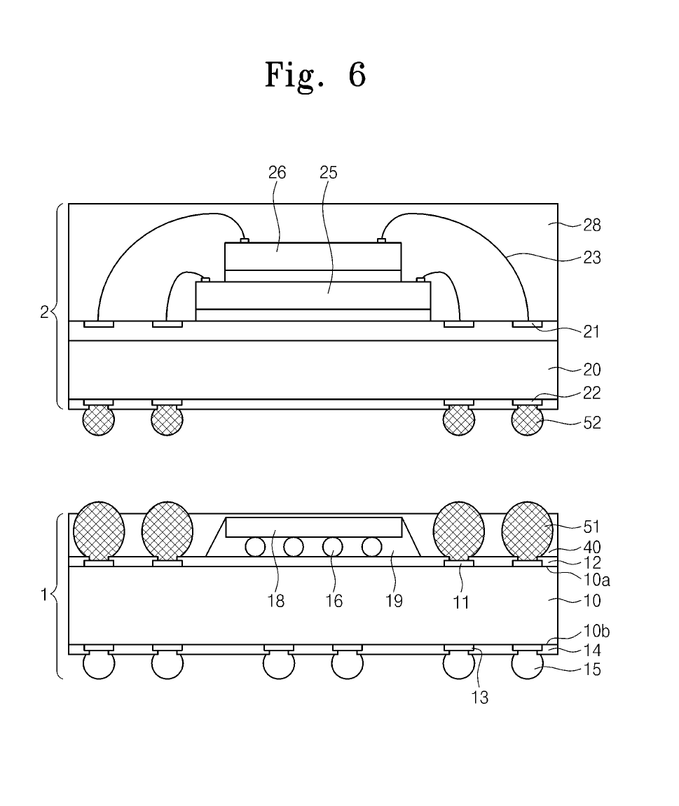

Referring to FIG. 6, the upper semiconductor package 2 may be prepared. In example embodiments, the upper semiconductor package 2 may include two upper semiconductor chips 25 and 26, which may be mounted on the upper package substrate 20 in a wire bonding manner. The upper package substrate 20 may include a plurality of insulating layers. The first connection pads 21 may be formed on a top surface of the upper package substrate 20, and the second connection pads 22 may be formed on a bottom surface of the upper package substrate 20. In example embodiments, the upper semiconductor chips 25 and 26 may be electrically connected to the first connection pads 21 through the wire 23. The upper semiconductor chips 25 and 26 and the upper package substrate 20 may be covered with the upper molding layer 28.

Preliminary solder balls 52 may be formed on the second connection pads 22. The preliminary solder balls 52 may be formed to be in contact with the second connection pads 22. In example embodiments, the preliminary solder balls 52 may be formed at positions facing the inner solder balls 51. The preliminary solder balls 52 may be soldered to the inner solder balls 51, in a subsequent process.

Referring to FIG. 7, the inner solder balls 51 and the preliminary solder balls 52 may be soldered to each other to form the connection solder balls 50. In example embodiments, the soldering process may include heating the preliminary solder ball 52 and the inner solder ball 51 to a temperature of, for example, 180-240° C. to melt them. Since the connection solder ball 50 is formed through melting of the preliminary solder ball 52 and the inner solder ball 51, the preliminary solder ball 52 and the inner solder ball 51 may form a single body (i.e., the connection solder ball 50) without an internal interface. For example, each of the connection solder balls 50 may include the upper region 50a and the lower region 50b that are continuously connected to each other. Accordingly, the semiconductor device 100 may be fabricated to include the lower semiconductor package 1 and the upper semiconductor package 2 mounted thereon.

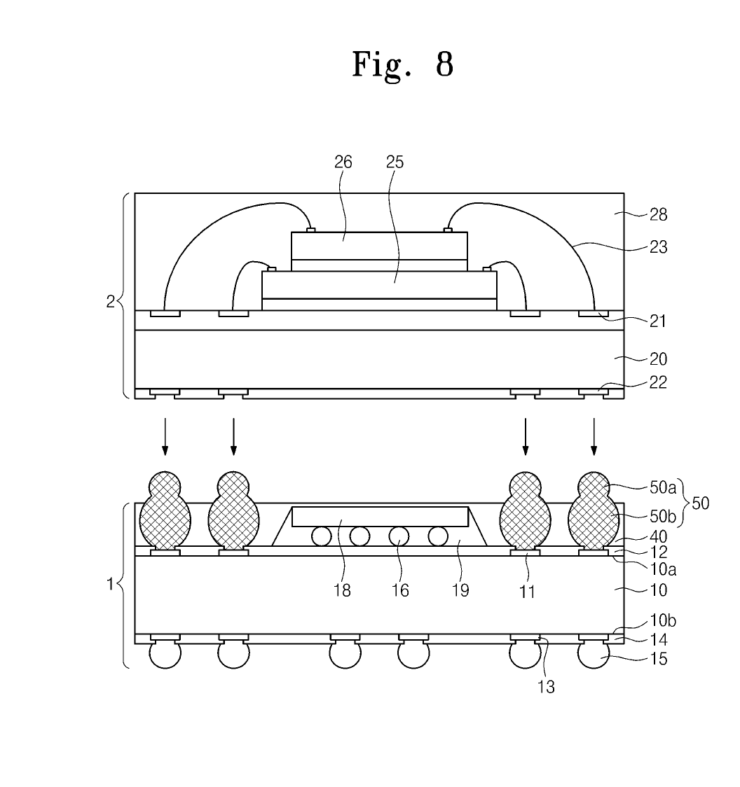

According to other embodiments of the present inventive concept, as shown in FIG. 8, for example, the preliminary solder balls 52 described with reference to FIG. 6 may be formed on the inner solder balls 51, respectively, not on the second connection pads 22 of the upper semiconductor package 2, and then, be soldered to the inner solder balls 51 to form the connection solder balls 50. Even in this case, each of the connection solder balls 50 may include the upper region 50a and the lower region 50b. Thereafter, the upper semiconductor package 2 may be mounted on the lower semiconductor package 1 provided with the connection solder balls 50.

Referring to FIG. 9, the connection solder ball 50 may be formed not to have a gap at an interface A with the lower molding layer 40. For example, the top surface of the lower region 50b of the connection solder ball 50 may be formed at a level higher than the top surface of the lower molding layer 40, thereby having no gap at the interface A with the lower molding layer 40. In other words, the side surface of the connection solder ball 50 that is lower than the top surface of the lower molding layer 40 may be wholly and directly covered with the lower molding layer 40. Accordingly, the connection solder balls 50 may be formed to have side surfaces in direct contact with the lower molding layer 40 without a gap, and this enables to improve contact reliability between the lower molding layer 40 and the connection solder balls 50.

Further, the top surface of the lower region 50b may be formed at a level higher than that of the lower molding layer 40, and thus, the inner solder ball 51 and the preliminary solder ball 52 may be in contact with each other at a level B higher than the top surface of the lower molding layer 40 to form the connection solder ball 50.

Hereinafter, to provide a better understanding of example embodiments of the inventive concept, semiconductor devices according to comparative example embodiments will be described with reference to FIGS. 10 through 13.

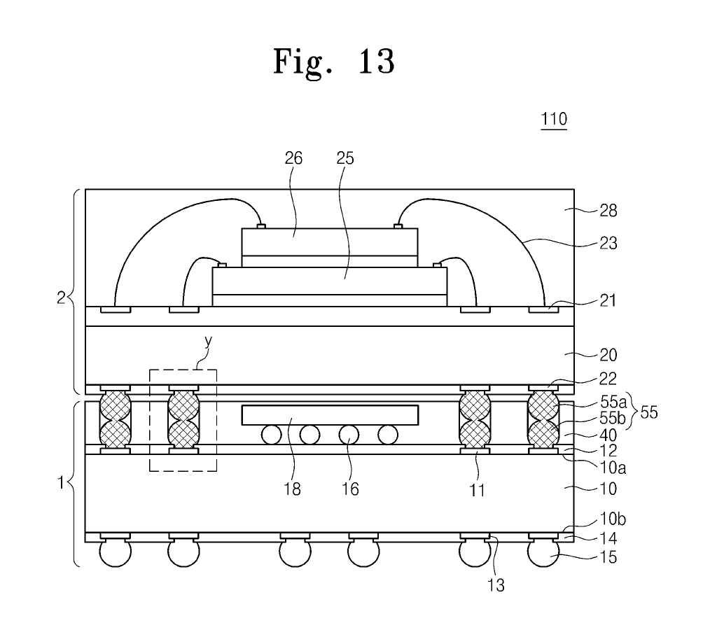

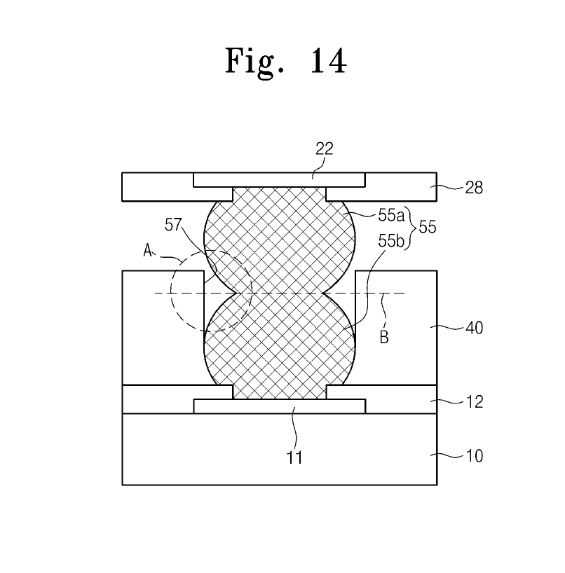

FIGS. 10 through 13 are sectional views illustrating a semiconductor device and a method of fabricating the same, according to comparative embodiments, and FIG. 14 is an enlarged sectional view of a portion Y of FIG. 13. For the sake of brevity, the elements and features of this example that are similar to those previously shown and described will not be described in much further detail.

Referring to FIG. 10, the lower package substrate 10 may be prepared to fabricate the lower semiconductor package 1. The plurality of the first ball lands 11 and the first insulating layer 12 partially covering the same may be provided on the top surface of the lower package substrate 10, and the plurality of second ball lands 13 and the second insulating layer 14 partially covering the same may be provided on the bottom surface of the lower package substrate 10. The lower semiconductor chip 18 may be mounted on the lower package substrate 10 using the internal terminals 16.

Inner solder balls 56 may be formed on the first ball lands 11 of the lower package substrate 10. The inner solder balls 56 may be formed on the lower package substrate 10 and around the lower semiconductor chip 18. The lower molding layer 40 may be formed to cover the lower package substrate 10, the lower semiconductor chip 18, and the inner solder balls 56.

This embodiment may differ from the example embodiments of the inventive concept, in that the lower molding layer 40 is formed to cover the inner solder balls 56. That is, according to the comparative embodiments, the top surface of the lower molding layer 40 may be formed at a level higher than that of the inner solder balls 56, and thus, the inner solder balls 56 may not be exposed by the lower molding layer 40.

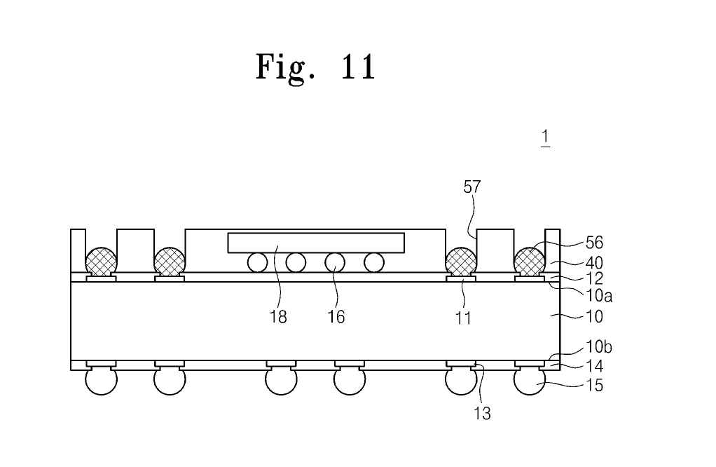

Referring to FIG. 11, the lower molding layer 40 may be partially removed to form connection holes 57 exposing the inner solder balls 56. The formation of the connection holes 57 may include removing a portion of the lower molding layer 40 using a laser. Thereafter, a cleaning process may be further performed to remove by-products, which may be produced during the formation of the connection holes 57, and then, the external terminals 15 may be formed on the second ball lands 13, respectively.

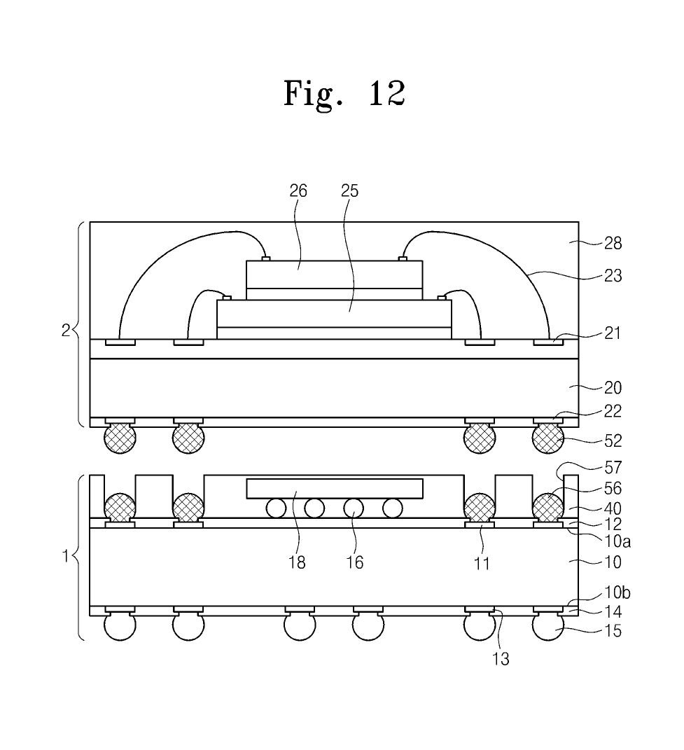

Referring to FIG. 12, the upper semiconductor package 2 may be mounted on the lower semiconductor package 1. For example, the upper semiconductor package 2 may include two upper semiconductor chips 25 and 26, which may be mounted on the upper package substrate 20. The first connection pads 21 may be formed on the top surface of the upper package substrate 20, and the second connection pads 22 may be formed on the bottom surface of the upper package substrate 20. The upper semiconductor chips 25 and 26 and the upper package substrate 20 may be covered with the upper molding layer 28.

The preliminary solder balls 52 may be formed on the second connection pads 22. The preliminary solder balls 52 may be formed to be in contact with the second connection pads 22, and may be formed at positions facing the inner solder balls 56 and the connection holes 57.

Referring to FIG. 13, the inner solder balls 56 and the preliminary solder balls 52 may be soldered to each other to form connection solder balls 55. The soldering process may include heating the preliminary solder balls 52 and the inner solder balls 56 to a temperature of, for example, 180-240° C. to melt them, and thus, the preliminary solder ball 52 and the inner solder ball 56 may form a single body (i.e., the connection solder ball 55) without an internal interface. Accordingly, each of the connection solder balls 55 may include an upper region 55a and a lower region 55b.

Referring to FIG. 14, for a semiconductor device 110 according to the comparative embodiment, a gap may be formed at an interface between the connection solder ball 55 and the lower molding layer 40. This is because the top surface of the inner solder ball 56 is formed at a level lower than the top surface of the lower molding layer 40 and the connection hole 57 is subsequently formed to expose the inner solder ball 56. For example, a side surface of the connection solder ball 55 at a level of the top surface of the lower molding layer 40 may be spaced apart from an upper portion of the lower molding layer 40. This may lead to deterioration in contact reliability between the lower molding layer 40 and the connection solder balls 55.

In addition, since the top surface of the lower region 55b of the connection solder ball 55 is formed at a level lower than that of the lower molding layer 40, the inner solder ball 56 and the preliminary solder ball 52 may be in contact with each other at a level lower than the top surface of the lower molding layer 40, and thus, a portion of the side surface of the connection solder ball 55 may be spaced apart from the lower molding layer 40.

By contrast, in the case of the semiconductor device 100 of FIG. 9, the inner solder ball 51 may have the top surface formed at a level higher than that of the lower molding layer 40, and this prevents a gap from being formed at the interface A with the lower molding layer 40. Due to the absence of the gap, contact reliability between the lower molding layer 40 and the connection solder balls 50 can be improved in the semiconductor device 100 of FIG. 9. Furthermore, the processes of forming and cleaning the connection holes 57 described with reference to FIG. 12 can be omitted in the fabrication method according to example embodiments of the inventive concept.

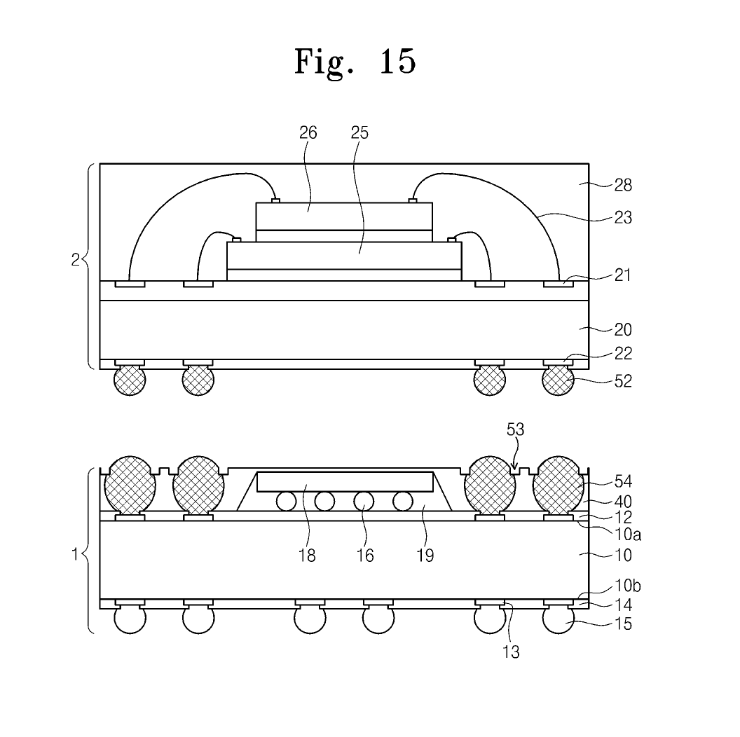

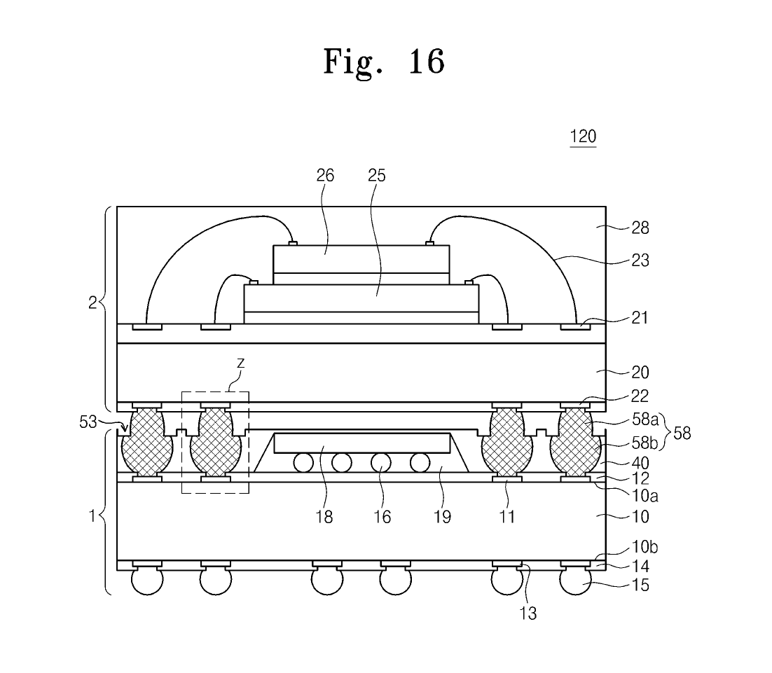

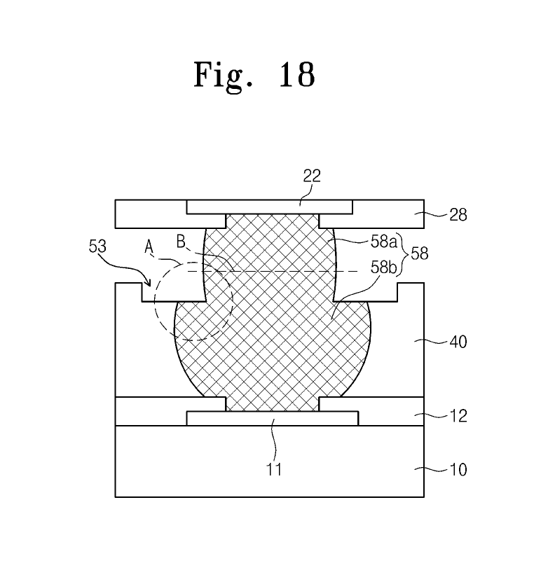

FIGS. 15 through 17 are sectional views illustrating a semiconductor device and a method of fabricating the same according to other example embodiments of the inventive concept, and FIG. 18 is an enlarged sectional view of a portion Z of FIG. 16.

Referring to FIG. 15, the lower semiconductor package 1 may be provided to include the lower package substrate 10, at least one semiconductor chip 18 mounted on the lower package substrate 10, the lower molding layer 40 covering the lower package substrate 10 and the semiconductor chip 18, and the upper semiconductor package 2 may be provided to include the upper package substrate 20, the semiconductor chips 25 and 26 mounted on the upper package substrate 20, the second connection pads 22 disposed on the bottom surface of the upper package substrate 20, and the preliminary solder balls 52 disposed on the second connection pads 22. For the sake of brevity, the elements and features of this example that are similar to those previously shown and described will not be described in much further detail.

Inner solder balls 54 may be formed on the lower package substrate 10 and around the lower semiconductor chip 18. The top surfaces of the inner solder balls 54 may be formed at a level higher than that of the lower molding layer 40, and thus, the upper portions of the inner solder balls 54 may protrude from the lower molding layer 40.

In the present embodiment, a process of partially removing the molding layer 40 may be further performed. For example, the molding layer 40 may be partially recessed around the inner solder balls 54 by the removing process, thereby forming grooves 53. Each of the grooves 53 may be formed along an exposed periphery of the corresponding one of the inner solder balls with a predetermined width. As the result of the formation of the grooves 53, the molding layer 40 may have a reduced effective thickness in the process of soldering the preliminary solder balls 52 to the inner solder balls 54, and this enables to form locally the solder balls 52 and 54 within predetermined regions. The formation of the grooves 53 may include partially removing the molding layer 40 around the inner solder balls 54 using a laser. In example embodiments, the inner solder balls 54 may be partially removed during the formation of the grooves 53.

Referring to FIG. 16, the upper semiconductor package 2 may be aligned in such a way that the preliminary solder balls 52 thereon face the inner solder balls 54, and then, the preliminary solder balls 52 may be soldered to the inner solder balls 54 to from connection solder balls 58. As the result of the soldering process, each of the connection solder balls 58 may include an upper region 58a and a lower region 58b. According to the present embodiment, the upper regions 58a of the connection solder balls 58 may be formed to have the substantially same width, because the grooves 53 are formed around the inner solder balls 54, respectively.

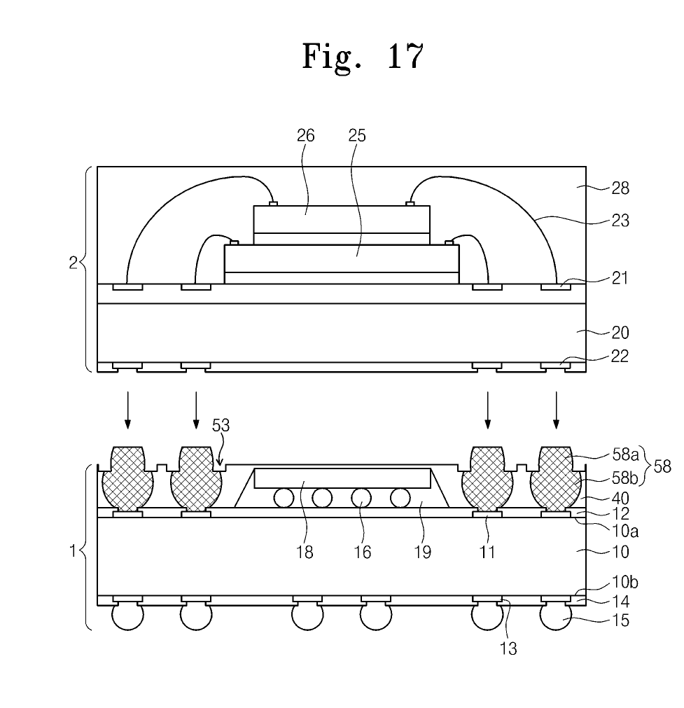

According to still another embodiment, as shown in FIG. 17, the preliminary solder balls 52 may be soldered on the inner solder balls 54, not on the second connection pads 22, to form the connection solder balls 58. Thereafter, an etching process may be performed to remove the molding layer 40 from peripheral regions of the connection solder balls 58 and form the grooves 53. Even in this case, each of the connection solder balls 58 may include the upper region 58a and the lower region 58b, which may be continuously connected to each other. Next, the upper semiconductor package 2 may be mounted on the connection solder balls 58 to form a semiconductor device 120 including the lower and upper semiconductor packages 1 and 2, as shown in FIG. 16.

Referring to FIG. 18, for the semiconductor device according to the present embodiment, no gap is formed at the interface A between the connection solder ball 58 and the lower molding layer 40. Further, the preliminary solder ball 52 may be in contact with the inner solder ball 54 at a level B higher than the top surface of the lower molding layer 40 through the connection hole 57 formed around the inner solder ball 54. In addition, the grooves 53 may be formed by partially removing the molding layer 40 from the peripheries of the connection solder balls 58, and thus, the solder balls may be locally formed within predetermined regions and may be formed to be in direct contact with the lower molding layer 40 without a gap. As a result, the semiconductor device 120 can be formed to have improved contact reliability.

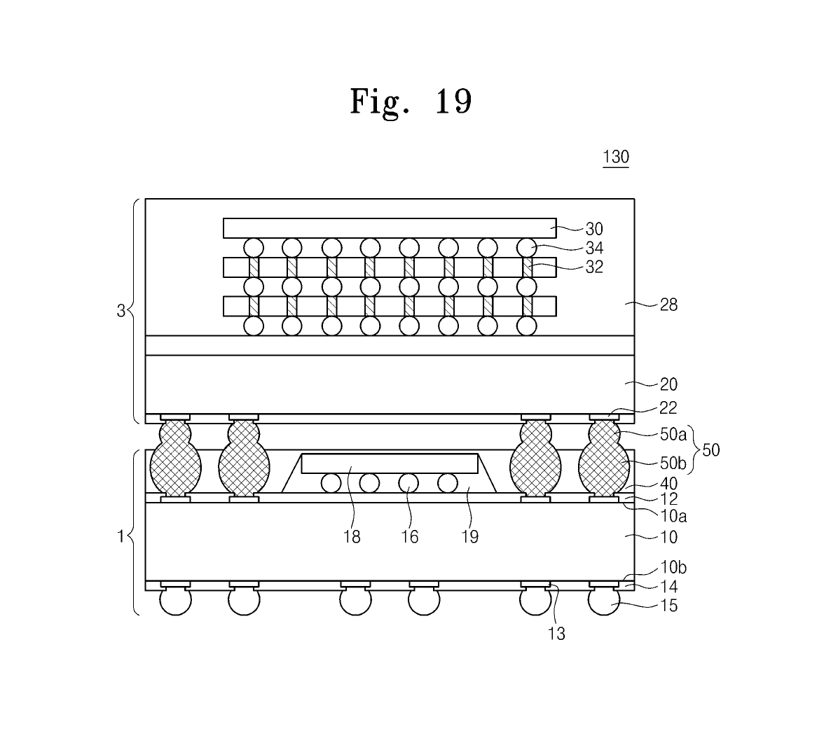

FIG. 19 is a sectional view illustrating a semiconductor device according to still other example embodiments of the inventive concept.

Referring to FIG. 19, a semiconductor device 130 according to the present embodiment may include the lower semiconductor package 1 described above and an upper semiconductor package 3 mounted thereon. The upper semiconductor package 3 may include a plurality of upper semiconductor chips 30, which may be mounted on the upper package substrate 20 in the flip chip bonding manner. For example, the upper semiconductor chips 30 may be sequentially stacked one over the other using upper inner solder balls 34 in the flip chip bonding manner. In addition, the upper semiconductor package 3 may include through vias 32, which may be overlapped to the upper inner solder balls 34 in a plan view. Except for these differences, the semiconductor device 130 may be configured to have the same technical features as the previous embodiments, in terms of the fabricating method and the structure.

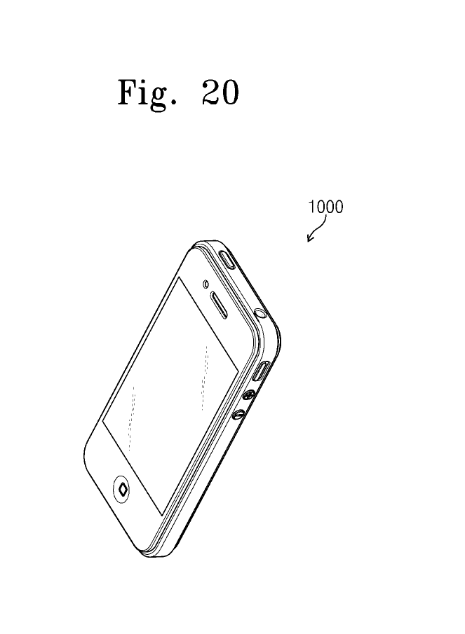

FIG. 20 is a perspective view illustrating an electronic system including at least one of semiconductor packages according to embodiments of the inventive concept.

Referring to FIG. 20, semiconductor packages according to the embodiments of the inventive concept may be applicable to an electronic system 1000, for example, a smart phone. The semiconductor packages according to the embodiments of the inventive concept may have the advantages which are capable of scaling down and/or realizing high performance. The electronic system including the semiconductor packages according to the embodiments is not limited to the smart phone. For example, the semiconductor packages according to the embodiments may be applicable to a mobile electronic product, a laptop computer, a portable computer, a portable multimedia player (PMP), an MP3 player, a camcorder, a web tablet, a wireless phone, a navigator or a personal digital assistant (PDA).

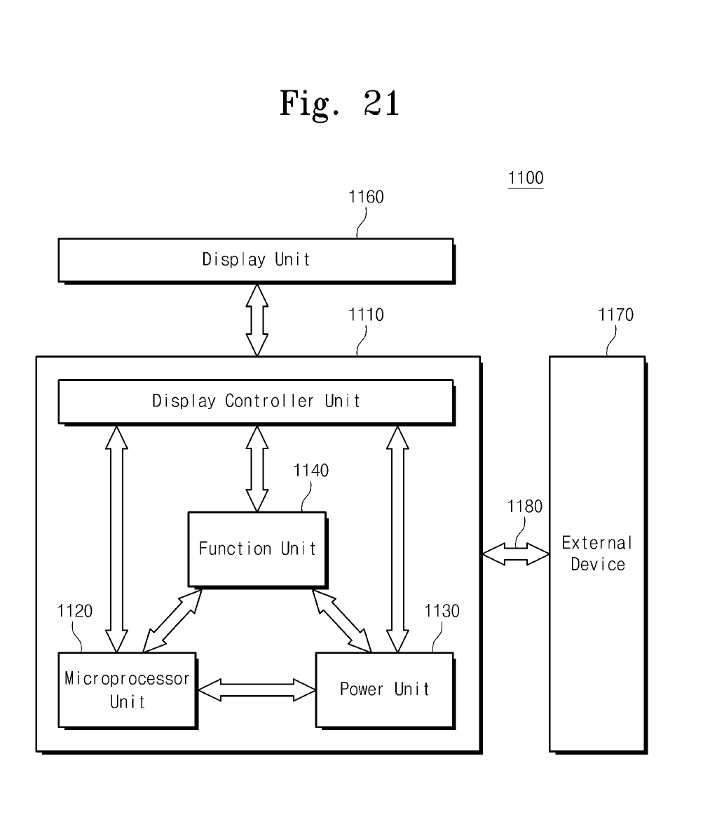

FIG. 21 is a schematic block diagram illustrating an electronic system including at least one of semiconductor packages according to embodiments of the inventive concept.

Referring to FIG. 21, the semiconductor package 100-104 described above may be applicable to an electronic system 1100. The electronic system 1100 may include a body 1110, a microprocessor unit 1120, a power unit 1130, a function unit 1140 and a display control unit 1150. The body 1110 may include a set board formed of a printed circuit board (PCB), and the microprocessor unit 1120, the power unit 1130, the function unit 1140 and the display control unit 1150 may be mounted on and/or in the body 1110.

The power unit 1130 may receive an electric power having a certain voltage from an external battery (not shown) and may generate a plurality of output power signals having different voltages, and the output power signals may be supplied to the microprocessor unit 1120, the function unit 1140 and the display control unit 1150.

The microprocessor unit 1120 may receive one of the output power signals from the power unit 1130 to control the function unit 1140 and the display unit 1160. The function unit 1140 may operate so that the electronic system 1100 executes one of diverse functions. For example, in the event that the electronic system 1100 is a mobile phone, the function unit 1140 may include various components which are capable of executing functions of the mobile phone, for example, a function of dialing, a function of outputting image signals to the display unit 1160 during communication with an external device 1170, and a function of outputting audio signals to speakers during communication with an external device 1170. Further, when the electronic system 1100 includes a camera, the function unit 1140 may correspond to a camera image processor CIP. Moreover, if the electronic system 1100 is connected to a memory card to increase a memory capacity, the function unit 1140 may correspond to a memory card controller. The function unit 1140 may communicate with the external device 1170 through a communication unit 1180 by wireless or cable. Furthermore, in the event that the electronic system 1100 needs a universal serial bus (USB) for function expansion, the function unit 1140 may be an interface controller. The semiconductor package 100-104 described above may be used in at least one of the microprocessor unit 1120 and the function unit 1140.

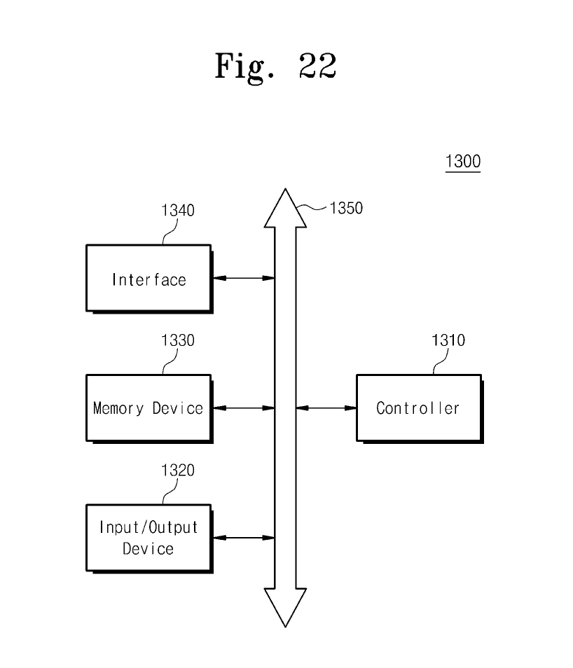

FIG. 22 is a block diagram illustrating an example of electronic systems including semiconductor packages according to the embodiments of the inventive concept.

Referring to FIG. 22, an electronic system 1300 according to an embodiment may include a controller 1310, an input/output (I/O) device 1320, a memory device 1330 and a data bus 1350. At least two of the controller 1310, the I/O device 1320 and the memory device 1330 may communicate with each other through the data bus 1350. The data bus 1350 may correspond to a path through which electrical signals are transmitted.

The controller 1310 may include at least one of a microprocessor, a digital signal processor, a microcontroller and a logic device. The logic device may have a similar function to any one of the microprocessor, the digital signal processor and the microcontroller. The controller 1310 and/or the memory device 1330 may include at least one of the semiconductor packages described in the above embodiments. The I/O device 1320 may include at least one of a keypad, a keyboard and a display device. The memory device 1330 may store data and/or commands executed by the controller 1310. The memory device 1330 may include a volatile memory device and/or a nonvolatile memory device. For example, the memory device 1330 may include a flash memory device to which the package techniques according to the embodiments are applied. That is, the flash memory device according to the embodiments may be mounted in an information processing system such as a mobile device or a desk top computer. The flash memory device may constitute a solid state disk (SSD). In this case, the solid state disk including the flash memory device may stably store a large capacity of data. The electronic system 1300 may further include an interface unit 1340. The interface unit 1340 may transmit data to a communication network or may receive data from a communication network. The interface unit 1340 may operate by wireless or cable. For example, the interface unit 1340 may include an antenna for wireless communication or a transceiver for cable communication. Although not shown in the drawings, the electronic system 1300 may further include an application chipset and/or a camera image processor.

According to example embodiments of the inventive concept, the connection solder balls interposed between the lower and upper semiconductor packages may be provided to protrude upward from a top surface of the lower molding layer, and thus, the semiconductor device may be configured not to have a gap between the connection solder balls and the lower molding layer. Accordingly, the semiconductor device can be formed to have improved contact reliability.

Furthermore, since the connection solder balls interposed between the lower and upper semiconductor packages may be provided to protrude upward from a top surface of the lower molding layer, etching and cleaning processes to expose the connection solder balls can be omitted in the method of fabricating a semiconductor device according to example embodiments of the inventive concept.

In addition, according to other example embodiments of the inventive concept, the lower molding layer may be partially removed to form grooves at the peripheries of the connection solder balls. This enables to form the solder balls within predetermined and localized regions.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A semiconductor device, comprising:
a lower semiconductor package including at least one lower semiconductor chip;
at least one upper semiconductor package mounted on the lower semiconductor package to include at least one upper semiconductor chip;
a molding layer provided between the lower and upper semiconductor packages; and
connection solder balls provided in the molding layer to electrically connect the lower and upper semiconductor packages to each other,
wherein each of the connection solder balls comprises a portion protruding upward from the molding layer, and there is no gap between the connection solder balls and the molding layer.

2. The device of claim 1, wherein each of the connection solder balls has a side surface that is positioned between top and bottom surfaces of the lower molding layer and is directly covered with the lower molding layer.

3. The device of claim 1, wherein each of the connection solder balls comprises an upper region and a lower region, and the maximum width of the lower region is greater than that of the upper region.

4. The device of claim 3, wherein the upper regions of the connection solder balls have substantially the same width.

5. The device of claim 1, wherein the lower semiconductor package comprises a lower package substrate and the at least one lower semiconductor chip provided on the lower package substrate, and
the connection solder balls are provided on the lower package substrate and around the at least one lower semiconductor chip.

6. The device of claim 1, wherein the upper semiconductor package comprises an upper package substrate, the at least one upper semiconductor chip provided on the upper package substrate, and an upper molding layer covering the upper package substrate and the at least one upper semiconductor chip.

7.-15. (canceled)

16. A semiconductor device, comprising:
a lower semiconductor package including at least one semiconductor chip on a lower substrate, inner solder balls surrounding the at least one semiconductor chip, and a molding layer fully covering the at least one semiconductor chip and mostly covering the inner solder balls, and
an upper semiconductor package including at least one semiconductor chip on a first surface and preliminary solder balls on a second surface, each of the preliminary solder balls being soldered to a corresponding one of the inner solder balls to form a connection so that no interface exists therebeteween.

17. The semiconductor device of claim 16, wherein the inner solder balls have a larger diameter and surface area than the preliminary solder balls such that the connection of each of the inner solder balls and the corresponding preliminary solder balls is disposed above the molding layer and there is no gap between the inner solder balls and the molding layer.

18.-20. (canceled)
